(19) United States
(12) Patent Application Publication
(10) Pub. No.: US 2024/0074293 A1
(43) Pub. Date: Feb. 29, 2024

(54) DISPLAY SUBSTRATE AND DISPLAY DEVICE

(71) Applicant: BOE TECHNOLOGY GROUP CO., LTD., Beijing (CN)

(72) Inventor: Wenxiu ZHU, Beijing (CN)

(73) Assignee: BOE TECHNOLOGY GROUP CO., LTD., Beijing (CN)

(21) Appl. No.: 18/260,814

(22) PCT Filed: Nov. 23, 2021
(86) PCT No.: PCT/CN2021/132346

§ 371 Date: Jul. 10, 2023

(51) Int. Cl. H10K 59/80; H10K 59/122; H10K 59/60

(52) U.S. Cl. CPC H10K 59/878; H10K 59/122; H10K 59/60

(57) ABSTRACT

Embodiments of the present disclosure provide a display substrate. The display substrate includes: a substrate; a photosensitive device located on the substrate; a reflective structure located on a side of the photosensitive device away from the substrate and surrounding the photosensitive device in a direction parallel to the substrate, the reflective structure includes a first surface facing the photosensitive device, a second surface facing away from the photosensitive device, and a side surface connecting the first surface and the second surface; and the light processing portion located on at least one of the first surface and the side surface of the reflective structure, a light reflectivity of the light processing portion is smaller than a light reflectivity of the reflective structure.

### CROSS REFERENCE TO RELATED APPLICATIONS

This application claims a national stage entry of PCT/CN2021/132346 filed on Nov. 23, 2021, the disclosure of which is incorporated herein by reference herein in their entirety as part of the present application.

### FIELD

The present disclosure relates to a field of display technology, and in particular, to a display substrate and a display device.

### BACKGROUND

A fingerprint is a biological feature that can be distinguished from other people. It is composed of ridges and valleys on a surface of a skin, which determine a uniqueness of a fingerprint pattern. A display device with a fingerprint recognition function has been used for personal identity verification, which increases a security of the display device.

### SUMMARY

Embodiments of the present disclosure provide a display substrate and a display device.

According to a first aspect of the present disclosure, a display substrate is provided. The display substrate comprises: a substrate; a photosensitive device located on the substrate; a reflective structure located on a side of the photosensitive device away from the substrate and surrounding the photosensitive device in a direction parallel to the substrate, the reflec6tive structure comprises a first surface facing the photosensitive device, a second surface facing away from the photosensitive device, and a side surface connecting the first surface and the second surface; and a light processing portion located on at least one of the first surface and the side surface of the reflective structure, and a light reflectivity of the light processing portion is smaller than a light reflectivity of the reflective structure.

In the embodiment of the present disclosure, the display substrate further comprises a light emitting device for display, which is located on the substrate and spaced apart from the photosensitive device along a direction parallel to the substrate, wherein the light emitting device comprises a first conductive layer, a light emitting layer and a second conductive layer sequentially disposed in a direction away from the substrate, wherein the reflective structure comprises a first reflective structure, and the second conductive layer comprises the first reflective structure, the light processing portion comprises a first light processing portion located on the first surface of the first reflective structure.

In the embodiment of the present disclosure, the display substrate further comprises a pixel defining layer on the substrate, the pixel defining layer having a first opening for defining the photosensitive device and a second opening for defining the light emitting device.

In the embodiment of the present disclosure, a material of the second conductive layer comprises a transparent conductive material, wherein the second conductive layer continuously covers the pixel defining layer and the photosensitive device.

In the embodiment of the present disclosure, the first reflective structure comprises a portion where a vertical projection of the second conductive layer on the substrate overlaps with a vertical projection of the pixel defining layer on the substrate.

In the embodiment of the present disclosure, the first light processing portion is located between the reflective structure and the pixel defining layer.

In the embodiment of the present disclosure, the first light processing portion at least partially covers a top surface of the pixel defining layer away from the substrate.

In the embodiment of the present disclosure, the first light processing portion covers an entire top surface of the pixel defining layer.

In the embodiment of the present disclosure, the first light processing portion covers only an edge portion of the top surface of the pixel defining layer adjacent to the first opening and the second opening.

In the embodiment of the present disclosure, a size of the first light processing portion in a direction parallel to the substrate is 3 micrometers.

In the embodiment of the present disclosure, the first light processing portion comprises a portion of the pixel defining layer adjacent to the photosensitive device.

In the embodiment of the present disclosure, a portion of the pixel defining layer adjacent to the photosensitive device comprises a light-absorbing material, and a portion of the pixel defining layer not adjacent to the photosensitive device comprises a transparent material.

In the embodiment of the present disclosure, the reflective structure further comprises a second reflective structure, the second reflective structure is located on a side of the first reflective structure away from the substrate, the light processing portion further comprises a second light processing portion located on the first surface of the second reflective structure.

In the embodiment of the present disclosure, the light processing portion further comprises a third light processing portion located on the side surface of the second reflective structure adjacent to the photosensitive device.

In the embodiment of the present disclosure, the second reflective structure has an opening, wherein a vertical projection of the opening on the substrate at least partially overlaps with a vertical projection of the photosensitive device on the substrate, wherein the third light processing portion is located on a sidewall of the opening.

In the embodiment of the present disclosure, the display substrate further comprises a touch electrode layer located on a side of the second conductive layer away from the substrate, and the second reflective structure and the touch electrode layer are disposed on a same layer.

In the embodiment of the present disclosure, the light processing portion further comprises a fourth light processing portion, the fourth light processing portion is located on a surface of the touch electrode layer facing the substrate.

In the embodiment of the present disclosure, the display substrate further comprises a first protection layer located between the first reflective structure and the second reflective structure, and a black matrix layer, a polarizing layer, a second protection layer and a third protection layer located on a side of the second reflective structure away from the substrate and arranged in sequence.

In the embodiment of the present disclosure, materials of the second light processing portion, the third light processing portion, and the fourth light processing portion are the same as that of the black matrix layer.

According to a second aspect of the present disclosure, a display device is provided. The display device comprises the display substrate according to the first aspect of the present disclosure.

Further aspects and ranges of adaptations will become apparent from the description provided herein. It should be understood that various aspects of the present application may be implemented alone or in combination with one or more other aspects. It should also be understood that the description and specific examples are intended for purposes of illustration and are not intended to limit the scope of the application.

### BRIEF DESCRIPTION OF THE DRAWINGS

The drawings described herein are for illustrative purposes only of selected embodiments, not all possible implementations, and are not intended to limit the scope of the application in which:

FIG. 1 illustrates a schematic diagram of a display substrate.

FIG. 2 illustrates a schematic diagram of a display substrate according to an embodiment of the present disclosure.

FIG. 3 illustrates a schematic diagram of a display substrate according to an embodiment of the present disclosure.

FIG. 4 illustrates a schematic diagram of a display substrate according to an embodiment of the present disclosure.

FIG. 5 illustrates a schematic diagram of another display substrate according to an embodiment of the present disclosure.

FIG. 6 illustrates a schematic diagram of yet another display substrate according to an embodiment of the present disclosure.

FIG. 7 illustrates a schematic diagram of yet another display substrate according to an embodiment of the present disclosure.

FIGS. 8A to 8C illustrate top views of a display substrate according to an embodiment of the present disclosure.

FIG. 9 illustrates a schematic diagram of a structure of a display device according to the present disclosure.

### DETAILED DESCRIPTION

Various embodiments will now be described in detail with reference to the accompanying drawings, provided as illustrative examples of the present disclosure so that those skilled in the art can practice the present disclosure.

It should be noted that the following figures and examples are not meant to limit the scope of the present disclosure. Where certain elements of the present disclosure can be implemented in part or in whole using known components (or methods or procedures), only those parts of such known components (or methods or procedures) necessary for an understanding of the present disclosure will be described, and detailed descriptions of other parts of such known components will be omitted so as not to obscure the present disclosure. Further, the various embodiments encompass, by way of illustration, present and future known equivalents to the components referred to herein.

Unless the context otherwise expressly indicates, singular of the term used herein and in the appended claims includes the plural and vice versa. Thus, when referring to the singular, it usually includes the plural of the corresponding term. Similarly, the terms “comprising”, “including”, “containing”, “having” and their grammatical variations are intended to be inclusive and mean that there may be additional elements other than the listed elements. Where the term “example” is used herein, particularly when it follows a group of terms, the said “example” is exemplary and illustrative only, and should not be considered to be exclusive or broad. The terms “first”, “second”, “third”, etc. are only used for the purpose of description, and cannot be understood as indicating or implying the relative importance and formation order.

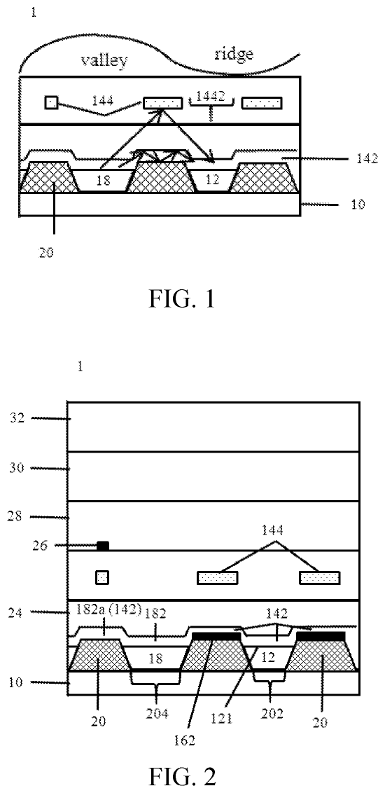

FIG. 1 shows a schematic diagram of a display substrate 1. As shown in FIG. 1, the display substrate 1 includes a substrate 10, a photosensitive device 12, reflective structures 142 and 144 (such as conductive structures of metal wiring) generally included in the display substrate 1, a light emitting device 18, and a pixel defining layer 20. The light emitted by the light emitting device 18 passes through the laminated structure of the display substrate 1 to reach a finger, and then is reflected by the ridges and valleys of the finger to form reflected light, and finally the reflected light passes through the opening 1442 to reach the photosensitive device 12. The photosensitive device can measure a ratio of the intensity of light reflected by the ridges to the intensity of light reflected by the valleys. The larger the ratio is, the higher the accuracy of fingerprint recognition is.

As shown in the light path of FIG. 1, due to the existence of the reflective structures 142 and 144, during the light emitted by the light emitting device 18 passes through the stacked structure of the display substrate 1, some of the light reflects back and forth between the upper and lower surfaces of the reflective structure 142 and finally reaches the photosensitive device 12, and some other of the light is reflected to the photosensitive device 12 by the lower surface of the reflective structure 144. However, considering that the reflectance difference between ridges and valleys is only 5%, the stray light reflected by these reflective structures will interfere with the light reflected by the finger, resulting in a smaller image difference between ridges and valleys (1:1.3), thereby reducing the accuracy of fingerprint recognition.

FIG. 2 shows a schematic diagram of a display substrate 1 according to an embodiment of the present disclosure. As shown in FIG. 2, the display substrate 1 may include a substrate 10, a photosensitive device 12, reflective structures 14 (142, 144), and a light processing portion 16 (162). The photosensitive device 12 is located on the substrate 10. The reflective structure 14 is located on the side 121 of the photosensitive device 12 away from the substrate 10, and surrounds the photosensitive device 12 along a direction parallel to the substrate 10, wherein the reflective structure 14 includes a first surface facing the photosensitive device 12 and a second surface facing away from the photosensitive device 12e, and a side surface connecting the first surface and the second surface. The light processing portion 16 is located on at least one of the first surface and the side surface of the reflective structure 14, wherein the light reflectivity of the light processing portion 16 is smaller than the light reflectivity of the reflective structure 14.

Using the display substrate according to the embodiment of the present disclosure, by setting the light processing portion on the reflective structure, it can prevent the reflective structure from reflecting light to the photosensitive device, thereby preventing the light reflected by the reflective structure from interfering with the light reflected by the finger, and improving the accuracy of fingerprint recognition, so that users can obtain a better fingerprint recognition experience.

Continuing to refer to FIG. 2, the display substrate 1 may further include a light emitting device 18 for display, which is located on the substrate 10 and spaced apart from the photosensitive device 12 along a direction parallel to the substrate 10. The light emitting device 18 may include a first conductive layer (e.g., an anode layer (not shown)), a light emitting layer (not shown) and a second conductive layer 182 (e.g., a cathode layer) sequentially disposed in a direction away from the substrate 10. The reflective structure 14 may include a first reflective structure 142, and the second conductive layer 182 includes the first reflective structure 142. That is, the second conductive layer 182 and the first reflective structure 142 are disposed on the same layer. In the present disclosure, the term “disposed on the same layer” refers to simultaneous formation by one patterning. The light processing portion 16 may include a first light processing portion 162 located on the first surface of the first reflective structure 142.

As shown in FIG. 2, the display substrate 1 further includes a pixel defining layer 20 on the substrate 10, and the pixel defining layer 20 has a first opening 202 and a second opening 204. The first opening 202 is used to define the photosensitive device 12, and the second opening 204 is used to define the light emitting device 18.

In an embodiment of the present disclosure, the material of the second conductive layer may include a transparent conductive material, such as indium tin oxide (ITO). In the embodiment shown in FIG. 2, the second conductive layer 182 continuously covers the pixel defining layer 20 and the photosensitive device 12.

As shown in FIG. 2, the first reflective structure 142 may include a portion 182a of the second conductive layer 182, and the vertical projection of the portion 182a on the substrate 10 overlaps with the vertical projection of the pixel defining layer 20 on the substrate 10.

In an embodiment of the present disclosure, the first light processing portion 162 may be located between the first reflective structure 142 and the pixel defining layer 142. In this embodiment, the first light processing portion 162 may at least partially cover the top surface of the pixel defining layer 20 on the side away from the substrate 10.

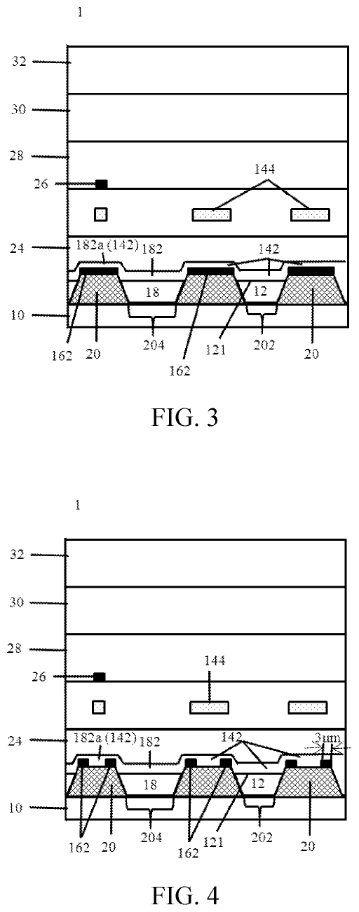

How the first light processing portion 162 covers the top surface of the pixel defining layer 20 will be described in detail below with reference to FIGS. 3 and 4.

In the embodiment shown in FIG. 3, the first light processing portion 162 can cover the entire top surface of the pixel defining layer 20, so that the first light processing portion 162 can absorb light reflected back and forth and thus transmitted between the first surface of the reflective structure 142 and the entire top surface of the pixel defining layer, further improving the accuracy of fingerprint recognition.

In the embodiment shown in FIG. 4, the first light processing portion 162 may only cover edge portions, adjacent to the first opening 202 and the second opening 204, of the top surface of the pixel defining layer 20. In this embodiment, the size of the first light processing portion 162, in the direction parallel to the substrate 10, is 3 micrometers. By exposing the non-edge portion of the pixel defining layer, the shielding of light can be reduced, so as to increase the aperture ratio of the display substrate 1. Using the display substrate 1 shown in FIG. 4 for fingerprint recognition, the ratio of the intensity of light reflected by the ridges to that of the valleys is 1:1.8.

FIG. 5 shows a schematic diagram of another display substrate 1 according to an embodiment of the present disclosure. As shown in FIG. 5, the first light processing portion 162 may include a portion 20a of the pixel defining layer 20 adjacent to the photosensitive device 12, that is, the first light processing portion 162 is integrated with the portion 20a. In this embodiment, the portion 20a of the pixel defining layer 20 adjacent to the photosensitive device 12 may include a light-absorbing material, and the portion 20b of the pixel defining layer 20 not adjacent to the photosensitive device 12 may include a transparent material. As shown in FIG. 5, the light emitting device 18 can emit light in various directions, and the light-absorbing material of the portion 20a can absorb the light emitted by the light emitting device 18 toward the photosensitive device 12, so as to reduce the light entering into the photosensitive device 12 through the portion 20a of the pixel defining layer 20, thereby avoiding the interference of the light on the light reflected by the finger, and further improving the accuracy of fingerprint recognition.

It should be noted that other structures and/or functions of the display substrate shown in FIGS. 3-5 are similar to those shown in FIG. 2, and will not be described again here.

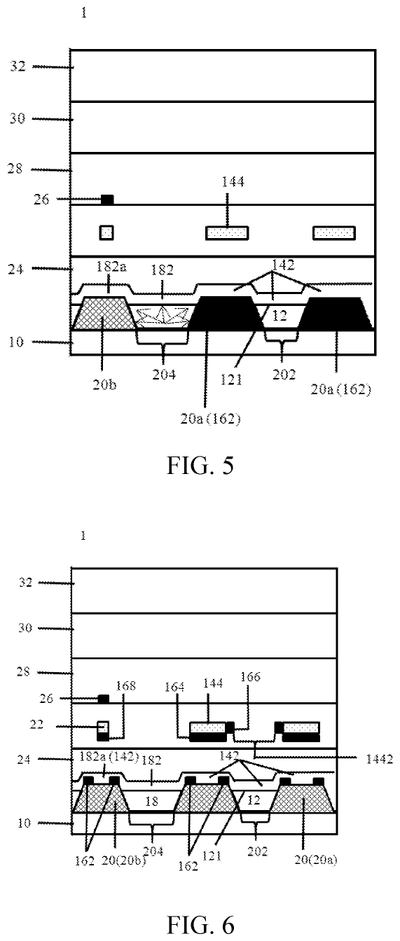

FIG. 6 shows a schematic diagram of yet another display substrate 1 according to an embodiment of the present disclosure. The display substrate shown in FIG. 6 is similar to the display substrate shown in FIG. 4, the difference is that the reflective structure 14 shown in FIG. 6 may also include a second reflective structure 144, the second reflective structure 144 is located on the side of the first reflective structure 142 away from the substrate 10, and the light processing portion 16 may also include a second light processing portion 164. The second light processing portion 164 is located on the first surface of the second reflective structure 144. In this embodiment, the second light processing portion 164 can absorb the light incident on the first surface of the second reflective structure 144, so as to prevent the first surface of the second reflective structure 144 from reflecting light to the photosensitive device 12, and further improving the accuracy of fingerprint recognition.

In the embodiment shown in FIG. 6, the light processing portion 16 may further include a third light processing portion 166, and the third light processing portion 166 is located on the side surface of the second reflective structure 144 adjacent to the photosensitive device 12, so as to prevent the side surface of the second reflective structure 144 from reflecting light to the photosensitive device 12, and further improving the accuracy of fingerprint recognition.

As shown in FIG. 6, the second reflective structure 144 may have an opening 1442, wherein the vertical projection of the opening 1442 on the substrate 10 and the vertical projection of the photosensitive device 12 on the substrate 10 at least partially overlap, so that the light reflected from the finger passes through the opening 1442 and reaches the photosensitive device 12 to realize fingerprint recognition. In this embodiment, the third light processing portion 166 is located on the sidewall of the opening 1442.

As shown in FIG. 6, the display substrate 1 may further include a touch electrode layer 22 located on a side of the second conductive layer 182 away from the substrate 10, and the second reflective structure 144 is disposed on the same layer as the touch electrode layer 22. The second reflective structure 144 and the touch electrode layer 22 are simultaneously formed by one patterning, thereby reducing the manufacturing process.

As shown in FIG. 6, the light processing portion 16 may further include a fourth light processing portion 168, and the fourth light processing portion 168 is located on the surface of the touch electrode layer 22 facing the substrate 10. The fourth light processing portion 168 can absorb the light incident on the surface of the touch electrode layer 22 facing the substrate 10, so as to prevent the surface of the touch electrode layer 22 from reflecting light to the photosensitive device 12, so as to further improve the accuracy of fingerprint recognition. Using the display substrate 1 shown in FIG. 6 for fingerprint recognition, the ratio of the intensity of light reflected by the ridges to that of the valleys can be increased to 1:2.2.

In an embodiment of the present disclosure, as shown in FIGS. 2-6, the display substrate 1 further includes a first protection layer 24 located between the first reflective structure 142 and the second reflective structure 144, and a black matrix layer 26, a polarizing layer 28, a second protection layer 30 and a third protection layer 32 located on the side of the second reflective structure 144 away from the substrate 10 and arranged in sequence. As shown in FIGS. 2-6, the vertical projection of the black matrix layer 26 on the substrate 10 is completely within the vertical projection of the portion 20b of the pixel defining layer on the substrate 10 to reduce the shielding of light and further increase the aperture ratio of the display substrate 1.

In an embodiment of the present disclosure, the material of the second light processing portion, the third light processing portion, and the fourth light processing portion may be the same as that of the black matrix layer. The first protection layer may be a thin film encapsulation layer, and the thin film encapsulation layer may adopt an inorganic/organic/inorganic three-layer structure or a multilayer structure. The touch electrode layer may include a single-layer metal grid or a multi-layer metal grid, and the grid avoids the light-emitting area of the display substrate. The polarizing layer may be a circular polarizer, the second protection layer may be an optical glue layer for bonding the third protection layer and the polarizing layer, and the third protection layer may be a cover layer.

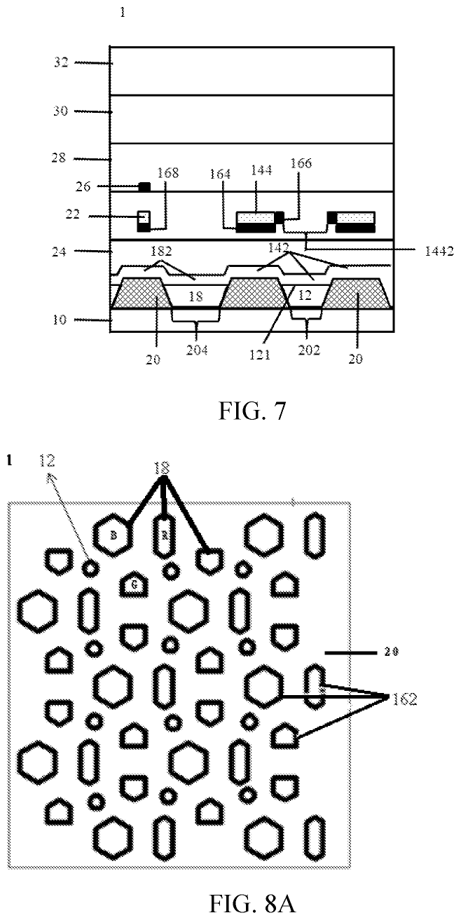

FIG. 7 shows a schematic diagram of yet another display substrate 1 according to an embodiment of the present disclosure. The display substrate shown in FIG. 7 is similar to the display substrate shown in FIG. 6. The difference is that the light processing portion 16 of the display substrate 1 shown in FIG. 7 only includes the second light processing portion 164, the third light processing portion 166, and the fourth light processing portion 168. Using the display substrate 1 shown in FIG. 7 for fingerprint recognition, the ratio of the intensity of light reflected by the ridges to that of the valleys is 1:1.8.

It should be noted that, in the embodiments of the present disclosure, the photosensitive device may be located in the display area of the display substrate, which may include a photosensor capable of sensing light and converting the light signal into an electrical signal, such as a thin film transistor, a photodiode or an organic photodiode.

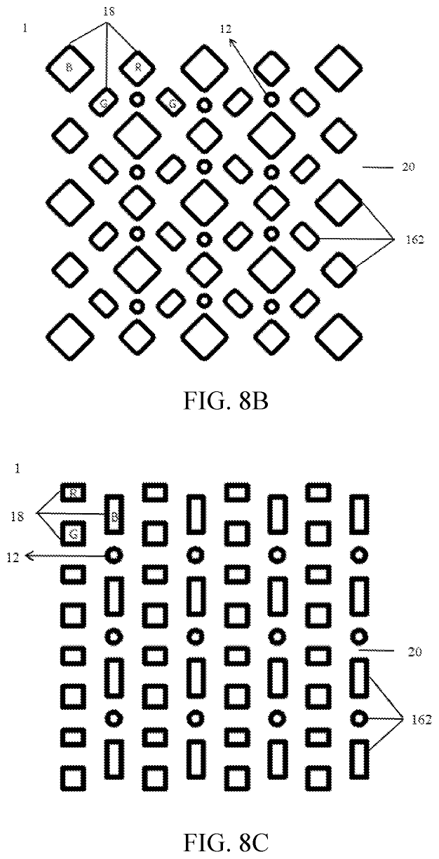

FIGS. 8A to 8C show top views of the display substrate 1 shown in FIG. 4. As shown in FIGS. 8A to 8C, the photosensitive device 12 and the light emitting device 18 are arranged in a direction parallel to the pixel defining layer 20. In this embodiment, each light emitting device 18 can be a pixel unit, and each pixel unit can include a red sub-pixel unit R, a green sub-pixel unit G, and a blue sub-pixel unit B, wherein, each sub-pixel unit in FIGS. 8A to 8C has a different arrangement. Each pixel unit can correspond to one photosensitive device to accurately identify fingerprints.

In addition, in the embodiments of the present disclosure, the light-absorbing material may include a black resin material, such as a resin material added with black light-shielding particles, or a black metal material or metal oxide material that appears black.

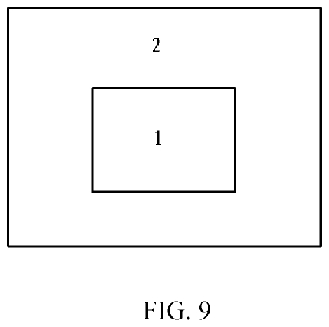

FIG. 9 shows a schematic diagram of the structure of a display device 2 according to the present disclosure. As shown in FIG. 9, the display device 2 includes the display substrate 1 as described above. Using the display device 2 according to the embodiment of the present disclosure, by setting the light processing portion on the reflective structure, it can prevent the reflective structure from reflecting light to the photosensitive device, thereby preventing the light reflected by the reflective structure from interfering with the light reflected by the finger, and improving the accuracy of fingerprint recognition, so that users can obtain a better fingerprint recognition experience.

In an embodiment of the present disclosure, the display device may be an organic light emitting diode. Alternatively, the display device may be a quantum dot display device or a micro LED display device.

The foregoing description of the embodiments has been provided for purposes of illustration and description. It is not intended to be exhaustive or to limit the application. Individual elements or features of a particular embodiment are generally not limited to that particular embodiment, but, where appropriate, are interchangeable and can be used in a selected embodiment, even if not specifically shown or described. The same can also be changed in many ways. Such changes are not to be considered a departure from the application, and all such modifications are included within the scope of the application.

1. A display substrate, comprising:
a substrate;
a photosensitive device located on the substrate;
a reflective structure, located on a side of the photosensitive device away from the substrate and surrounding the photosensitive device in a direction parallel to the substrate, wherein the reflective structure comprises a first surface facing the photosensitive device, a second surface facing away from the photosensitive device, and a side surface connecting the first surface and the second surface; and
a light processing portion located on at least one of the first surface and the side surface of the reflective structure, and a light reflectivity of the light processing portion is smaller than a light reflectivity of the reflective structure.

2. The display substrate of claim 1, further comprising a light emitting device for display, which is located on the substrate and spaced apart from the photosensitive device along a direction parallel to the substrate, wherein the light emitting device comprises a first conductive layer, a light emitting layer and a second conductive layer sequentially disposed in a direction away from the substrate, wherein the reflective structure comprises a first reflective structure, and the second conductive layer comprises the first reflective structure, the light processing portion comprises a first light processing portion located on the first surface of the first reflective structure.

3. The display substrate of claim 2, further comprising a pixel defining layer on the substrate, the pixel defining layer having a first opening for defining the photosensitive device and a second opening for defining the light emitting device.

4. The display substrate of claim 3, wherein a material of the second conductive layer comprises a transparent conductive material, wherein the second conductive layer continuously covers the pixel defining layer and the photosensitive device.

5. The display substrate of claim 4, wherein the first reflective structure comprises a portion where a vertical projection of the second conductive layer on the substrate overlaps with a vertical projection of the pixel defining layer on the substrate.

6. The display substrate of claim 5, wherein the first light processing portion is located between the reflective structure and the pixel defining layer.

7. The display substrate of claim 6, wherein the first light processing portion at least partially covers a top surface of the pixel defining layer away from the substrate.

8. The display substrate of claim 7, wherein the first light processing portion covers an entire top surface of the pixel defining layer.

9. The display substrate of claim 7, wherein the first light processing portion covers only an edge portion of the top surface of the pixel defining layer adjacent to the first opening and the second opening.

10. The display substrate of claim 9, wherein a size of the first light processing portion in a direction parallel to the substrate is 3 micrometers.

11. The display substrate of claim 5, wherein the first light processing portion comprises a portion of the pixel defining layer adjacent to the photosensitive device.

12. The display substrate of claim 11, wherein a portion of the pixel defining layer adjacent to the photosensitive device comprises a light-absorbing material, and a portion of the pixel defining layer not adjacent to the photosensitive device comprises a transparent material.

13. The display substrate of claim 2, wherein the reflective structure further comprises a second reflective structure, the second reflective structure is located on a side of the first reflective structure away from the substrate, the light processing portion further comprises a second light processing portion located on the first surface of the second reflective structure.

14. The display substrate of claim 13, wherein the light processing portion further comprises a third light processing portion located on the side surface of the second reflective structure adjacent to the photosensitive device.

15. The display substrate of claim 14, wherein the second reflective structure has an opening, wherein a vertical projection of the opening on the substrate at least partially overlaps with a vertical projection of the photosensitive device on the substrate, wherein the third light processing portion is located on a sidewall of the opening.

16. The display substrate of claim 15, further comprising a touch electrode layer located on a side of the second conductive layer away from the substrate, and the second reflective structure and the touch electrode layer are disposed on a same layer.

17. The display substrate of claim 16, wherein the light processing portion further comprises a fourth light processing portion, the fourth light processing portion is located on a surface of the touch electrode layer facing the substrate.

18. The display substrate of claim 17, further comprising a first protection layer located between the first reflective structure and the second reflective structure, and a black matrix layer, a polarizing layer, a second protection layer and a third protection layer located on a side of the second reflective structure away from the substrate and arranged in sequence.

19. The display substrate of claim 18, wherein materials of the second light processing portion, the third light processing portion, and the fourth light processing portion are the same as that of the black matrix layer.

20. A display device, comprising the display substrate of claim 1.
